(19) United States
(12) Patent Application Publication
(10) Pub. No.: US 2026/0324289 A1
(43) Pub. Date: Oct. 15, 2026

(54) METHOD FOR MANUFACTURING A DONOR SUBSTRATE FOR USE IN A PIEZOELECTRIC THIN FILM TRANSFER METHOD

(71) Applicant: Soitec, BERNIN (FR)

(72) Inventors: Luciana Capello, BERNIN (FR); Gweltaz Gaudin, BERNIN (FR)

(21) Appl. No.: 19/117,156

(22) PCT Filed: Sep. 28, 2023
(86) PCT No.: PCT/EP2023/076889

§ 371 Date: Mar. 31, 2025

(30) Foreign Application Priority Data
Sep. 30, 2022 (FR) 2209971

(51) Int. Cl. H10N 30/072; H10N 30/086; H10N 30/853; H10N 30/88

(52) U.S. Cl. CPC H10N 30/072; H10N 30/086; H10N 30/853; H10N 30/88

(57) ABSTRACT

A method for manufacturing a donor substrate for transferring a piezoelectric film onto a final support substrate comprises providing a bulk handling substrate, in particular, based on silicon; implanting the bulk handling substrate to make an embrittlement zone in the bulk handling substrate; and providing a piezoelectric material above the bulk handling substrate. A donor substrate may be obtained by the manufacturing method disclosed herein. Such a donor substrate may be used in a method for transferring a piezoelectric thin film to another substrate.

### CROSS-REFERENCE TO RELATED APPLICATIONS

This application is a national phase entry under 35 U.S.C. § 371 of International Patent Application PCT/EP 2023/076889, filed Sep. 28, 2023, designating the United States of America and published as International Patent Publication WO 2024/068840 A1 on Apr. 4, 2024, which claims the benefit under Article 8 of the Patent Cooperation Treaty of French Patent Application Serial No. FR2209971, filed Sep. 30, 2022.

### TECHNICAL FIELD

The present disclosure relates to a method for manufacturing a donor substrate for use in a piezoelectric thin-film transfer method, and to a donor substrate obtained by such a method.

### BACKGROUND

A piezoelectric on insulator (POI) substrate comprises a thin film of piezoelectric material on a substrate. To manufacture such a POI substrate, the method used involves transferring the piezoelectric thin film from a thick substrate of piezoelectric material onto a final support substrate.

To achieve this, a donor substrate is first used, wherein a bulk substrate of piezoelectric material is bonded to a handling substrate by adhesive bonding, in particular, using a polymer film, or molecular bonding. Next, the donor substrate undergoes a thinning step of the piezoelectric bulk substrate to form a thinner piezoelectric film before being bonded to the support substrate. Finally, the piezoelectric film is mechanically or thermally transferred to the final substrate via a fracture zone previously created in the thinned piezoelectric film. The donor substrate is introduced into the method to limit the negative impact of the difference in coefficients of thermal expansion between the piezoelectric material and the final POI support substrate. Heat treatments are used to reinforce the bonding interface between the different substrates and to transfer the thin film. An example of this type of method is described in WO 2019/186032 A1 or WO 2019/002080 A1.

After a plurality of piezoelectric film transfers to final support substrates, the donor substrate remnant is disposed of as it can no longer be used in any manufacturing method due to a thickness limit below which a piezoelectric film transfer to a final substrate is no longer feasible. It is, therefore, necessary to use a new handling substrate to manufacture a new donor substrate in order to be able to carry out a piezoelectric thin film transfer method again for the manufacture of a POI substrate.

As a result, such a method has a high cost due to the need to use a new, freshly manufactured handling substrate for each method of manufacturing a donor substrate for the transfer of a piezoelectric thin film.

### BRIEF SUMMARY

One aim of the present disclosure is to remedy the aforementioned disadvantages and, in particular, to provide a method for manufacturing a donor substrate that makes it possible to reduce the cost of the manufacturing method and consequently also the cost of the piezoelectric film transfer method using such a donor substrate.

The subject matter of the disclosure is achieved by a piezoelectric thin film transfer method comprising: a) providing a donor substrate comprising a bulk handling substrate, in particular, based on silicon, with an embrittlement zone, and a piezoelectric material, the piezoelectric material being above the bulk handling substrate, b) forming an embrittlement zone inside the piezoelectric material of the donor substrate, in particular, by ion implantation, c) providing a final support substrate, in particular, based on silicon, d) attaching the donor substrate to the final substrate to obtain a donor substrate/final support substrate assembly, and e) fracturing the piezoelectric material along the embrittlement zone to separate a piezoelectric film from the remnant of the donor substrate.

According to one embodiment, step e) of fracturing the piezoelectric material along the embrittlement zone can be performed at a lower temperature than the temperature used to perform fracturing at the embrittlement zone of the bulk handling substrate of the donor substrate.

According to one embodiment, steps a) to e) can be repeated at least once, and from the second iteration onwards, step a) can be carried out with the remnant of the donor substrate obtained at the end of step e) of the previous iteration.

In one embodiment, steps a) to e) can be repeated as long as the thickness of the piezoelectric film of the donor substrate remnant obtained in step e) is greater than 5 μm.

In one embodiment, a step f) of fracturing the donor substrate remnant at the embrittlement zone of the bulk handling substrate can be carried out after step e).

According to one embodiment, the fracturing step f) can be performed when the piezoelectric film thickness of the donor substrate remnant obtained in step e) is equal to or less than 5 μm, to obtain a bulk handling substrate remnant.

In one embodiment, step f) of fracturing the donor substrate remnant along the embrittlement zone of the bulk handling substrate can be carried out by heat treatment.

According to one embodiment, the donor substrate provided in step a) can be obtained by implementing a method for manufacturing a donor substrate for transferring a piezoelectric film onto a final support substrate. The method for manufacturing a donor substrate for transferring a piezoelectric film onto a final support substrate may comprise the steps of: a) providing a bulk handling substrate, in particular, based on silicon; c) providing a piezoelectric material over the bulk handling substrate; and further comprising a step b) of implanting the bulk handling substrate to provide an embrittlement zone in the bulk handling substrate before the step of providing the piezoelectric material.

According to one embodiment, step a) of providing a bulk handling substrate (102) may comprise using the remnant of the bulk handling substrate obtained after step f) of the piezoelectric thin film transfer method previously described.

In one embodiment, a step g) for treating the surface of the bulk handling substrate remnant can be carried out after step f) of the piezoelectric thin-film transfer method described above.

According to one embodiment, step b) of implanting the bulk handling substrate can be performed with an implantation dose lower than 6×10¹⁶ cm⁻², in particular, lower than 5×10¹⁶ cm⁻², even more particularly, an implantation of Hydrogen H, Helium He or a co-implantation of Hydrogen H and Helium H.

According to one embodiment, a step c1) of providing an intermediate film between the bulk handling substrate and the piezoelectric material can be performed before the step c) of providing a piezoelectric material on top of the bulk handling substrate.

According to one embodiment, the step c) of providing a piezoelectric material above the bulk handling substrate may comprise providing a bulk substrate based on a piezoelectric material.

According to one embodiment, the step c) of providing a piezoelectric material above the bulk handling substrate may further comprise a step of assembling the bulk handling substrate with the piezoelectric material-based bulk substrate, in particular, by molecular bonding.

According to one embodiment, a step d) of thinning the piezoelectric material can be performed, in particular, by grinding, more particularly during the method for manufacturing a donor substrate for transferring a piezoelectric film onto a final support substrate.

According to one embodiment, the step d) of thinning the piezoelectric material can be performed to obtain a film of the piezoelectric material with a thickness of 30 μm or less, in particular, 20 μm or less.

According to one embodiment, the step c) of providing a piezoelectric material above the bulk handling substrate can be performed by epitaxial deposition of a piezoelectric material-based film on the bulk handling substrate.

According to one embodiment, the epitaxial deposition step can be carried out at a temperature below 950 °C, in particular, below 900°.

According to one embodiment, the donor substrate provided in step a) of the transfer method can be characterized in that the embrittlement zone is positioned at a depth t in the bulk handling substrate of 500 nm, in particular, at a depth t in the bulk handling substrate of 300 nm, even more in particular, at a depth t in the bulk handling substrate of less than 300 nm.

According to one embodiment, the donor substrate provided in step a) of the transfer method can be characterized in that the bulk handling substrate is a Silicon Carbide SiC substrate and the piezoelectric material is Gallium Nitride GaN.

The subject matter of the present disclosure may also be achieved by a method for manufacturing a donor substrate for transferring a piezoelectric film onto a final support substrate, comprising the steps of: a) providing a bulk handling substrate, in particular, based on silicon; c) providing a piezoelectric material over the bulk handling substrate; wherein the method further comprises a step b) of implanting the bulk handling substrate to provide an embrittlement zone in the bulk handling substrate before the step c) of providing the piezoelectric material.

Thus, the donor substrate manufactured by the method according to the present disclosure can be fractured at the bulk handling substrate in a subsequent step. Fracturing at the embrittlement zone of the bulk handling substrate of the donor substrate produces a bulk handling substrate remnant that can be used again in subsequent methods. In this way, the cost associated with manufacturing a bulk handling substrate can be reduced by reusing or recycling part of the bulk handling substrate.

According to one embodiment, step b) of implanting the bulk handling substrate can be performed with an implantation dose lower than 6×10¹⁶ cm⁻², in particular, lower than 5×10¹⁶ cm⁻², even more particularly, an implantation of Hydrogen H, Helium He or a co-implantation of Hydrogen and Helium H/He.

In this way, the embrittlement zone in the bulk handling substrate is positioned at a depth in the bulk handling substrate of less than 500 nm, in particular, 300 nm. This depth makes it possible to produce a thin film of the bulk handling substrate to be removed in the corresponding fracturing step. In this way, the bulk handling substrate remnant has a thickness that is still viable for reuse in a subsequent method.

According to one embodiment, a step cl) of providing an intermediate film between the bulk handling substrate and the piezoelectric material can be performed prior to step c).

Thus, the assembly between the bulk handling substrate and the piezoelectric material can be improved by the presence of the intermediate film. In addition, the intermediate film simplifies the formation of the assembly structure.

According to one embodiment, step c) of providing a piezoelectric material above the bulk handling substrate may comprise providing a bulk substrate based on a piezoelectric material.

The method according to the disclosure can use a wide variety of piezoelectric materials, which play a major role in devices exploiting the piezoelectric effect. For example, Lithium Tantalate (LTO), Lithium Niobate (LNO), Aluminum Nitride (AIN), Lead Zirconate Titanate (PZT), Langasite (LGS) or Langatate (LGT) can be used.

According to one embodiment, step c) may further comprise a step of assembling the bulk handling substrate with the bulk substrate based on piezoelectric material, in particular, by molecular bonding.

In this way, the assembly step enables a large number of different materials to be combined. In addition, the interface between the bulk handling substrate and the piezoelectric material is a stable assembly interface.

In one embodiment, a step d) of thinning the piezoelectric material can be carried out, in particular, by grinding.

In this way, a piezoelectric film of the desired thickness can be obtained from a thick piezoelectric substrate, and the donor substrate produced using the method of the present disclosure can be used to transfer a piezoelectric thin film onto a support substrate to obtain a piezoelectric on insulator (POI) substrate with the desired properties.

According to one embodiment, the thinning step d) can be performed to obtain a piezoelectric material thickness of 30 μm or less, in particular, 20 μm or less.

The donor substrate thus produced by the method according to the present disclosure can be used as a donor substrate in a subsequent film transfer method for transferring a thin film of the piezoelectric material onto a final support substrate to form a piezoelectric on insulator (POI) substrate. In a method for manufacturing a POI substrate, the piezoelectric material and the final support substrate material have very different coefficients of thermal expansion, resulting in significant deformation of the assembly. In such a method, thanks to the use of a donor substrate, the thick piezoelectric substrate is held between the handling substrate and the support substrate. The choice of materials and thicknesses for the handling substrate and the final support substrate reduces the impact of the coefficients of thermal expansion and, thus, minimizes the deformation of the assembly when applying heat treatments during the method for manufacturing a piezoelectric on insulator (POI) substrate. For example, the difference in the coefficient of thermal expansion between the handling substrate material and the final support substrate material is less than or equal to 5%, and preferably equal to or close to 0%.

According to one embodiment, step c) of providing a piezoelectric material can be performed by epitaxial deposition of the piezoelectric material-based film.

In this way, the method enables a film of piezoelectric material to be obtained in a controlled manner, with a desired, predetermined thickness and a quality suitable for use in SAW devices. For example, a film of Gallium Nitride GaN can be obtained, which is an interesting piezoelectric material for the manufacture of POI substrates.

According to one embodiment, the epitaxial deposition step can be carried out at a temperature below 950 °C, in particular, below 900°.

In this way, a thick film of piezoelectric material can be obtained of good quality for use in SAW devices at a later date. For example, the bulk handling substrate can be a Silicon Carbide SiC substrate, and the piezoelectric material can be a Gallium Nitride GaN film.

The subject matter of the present disclosure also includes a donor substrate, in particular, a donor substrate obtained by the method described above, comprising a bulk handling substrate, in particular, based on Silicon; a piezoelectric material above the bulk handling substrate; wherein the bulk handling substrate comprises an embrittlement zone.

Such a donor substrate, in particular, one manufactured using the method described herein, can be used to transfer a piezoelectric thin film onto a support substrate to create a piezoelectric on insulator (POI) substrate. In addition, the presence of the embrittlement zone in the bulk handling substrate enables part of the donor substrate to be recycled by fracturing the donor substrate at the embrittlement zone, once the piezoelectric thin-film transfer method has been completed. Fracturing along the embrittlement zone of the handling substrate can be achieved by thermal or mechanical treatment.

According to one embodiment, the embrittlement zone in the bulk handling substrate can be positioned at a depth t in the bulk handling substrate of 500 nm, particularly at a depth t of 300 nm within the bulk handling substrate, even more particularly at a depth t of less than 300 nm within the bulk handling substrate.

According to one embodiment, the bulk handling substrate can be a Silicon Carbide SiC substrate, and the piezoelectric material can be a Gallium Nitride GaN film.

This combination of materials is very interesting for its subsequent use in power devices addressing voltages of 1200V or more, or in Radio Frequency (RF) or optoelectronic devices such as micro-LEDs.

The subject matter of the present disclosure also includes a piezoelectric thin film transfer method comprising: a) providing a donor substrate comprising a bulk handling substrate with an embrittlement zone as previously described or obtained by implementing a manufacturing method as previously described, b) forming an embrittlement zone inside the piezoelectric material of the donor substrate, in particular, by ion implantation, c) providing a final support substrate, in particular, based on silicon, d) attaching the donor substrate to the final support substrate to obtain a donor substrate/final support substrate assembly, and e) fracturing the piezoelectric material along the embrittlement zone to separate a piezoelectric film from the remnant of the donor substrate.

In a method for manufacturing a POI substrate, the piezoelectric material and the support substrate material have very different coefficients of thermal expansion, resulting in significant deformation of the assembly. In such a method, thanks to the use of a donor substrate, the thick piezoelectric substrate is held between the handling substrate and the final support substrate. The choice of materials and thicknesses for the handling substrate and the final support substrate make it possible to ensure a certain symmetry of the coefficients of thermal expansion, and thus minimizes the deformation of the assembly when applying heat treatments during the method for manufacturing a piezoelectric on insulator (POI) substrate. For example, the difference in the coefficient of thermal expansion between the handling substrate material and the final support substrate material is less than or equal to 5%, and preferably equal to or close to 0%.

According to one embodiment, step e) of fracturing the piezoelectric material along the embrittlement zone can be performed at a lower temperature than the temperature used to perform fracturing at the embrittlement zone of the bulk handling substrate of the donor substrate.

Thus, only the fracturing at the embrittlement zone of the piezoelectric material is performed during this step of the method. The energy input required to make a fracture in the embrittlement zone of the bulk handling substrate is insufficient, as the fracture is made at a lower temperature than the energy input required.

According to one embodiment, steps a) to e) can be repeated at least once, and from the second iteration onwards, step a) is carried out with the remnant of the donor substrate obtained at the end of step e) of the previous iteration.

In this way, the donor substrate remnant can be recycled and even reused several times. This reduces the cost of the method, as a plurality of POI substrates can be produced from a single donor substrate.

In one embodiment, steps a) to e) can be repeated as long as the thickness of the piezoelectric film of the donor substrate remnant obtained in step e) is greater than 5 μm.

Thus, the donor substrate remnant can be recycled and reused as long as the remaining piezoelectric film on the donor substrate remnant is of sufficient thickness to be able to transfer a piezoelectric thin film onto the final support substrate. This reduces the cost of the method, as a plurality of POI substrates can be produced from a single donor substrate.

In one embodiment, a step f) of fracturing the donor substrate remnant at the embrittlement zone of the bulk handling substrate can be carried out after step e).

In this way, a bulk handling substrate remnant can be obtained, with a free upper surface. This bulk handling substrate remnant can be reused to manufacture a new donor substrate as described above.

According to one embodiment, step f) of fracturing the donor substrate remnant at the embrittlement zone of the bulk handling substrate can be performed when the piezoelectric film thickness of the donor substrate remnant obtained in step e) is less than or equal to 5 μm to obtain a bulk handling substrate remnant.

The step of fracturing the remnant of the donor substrate separates the remaining piezoelectric film with a thickness of 5 μm or less, the intermediate film(s) and part of the bulk handling substrate. In this way, a bulk handling substrate remnant can be obtained, with a free top surface that can be reused to manufacture a new donor substrate as described above.

In one embodiment, step f) of fracturing the donor substrate remnant along the embrittlement zone of the bulk handling substrate can be carried out by heat treatment.

A significant heat input is required to make the fracture in the bulk handling substrate. This means that the fracturing of the bulk handling substrate at the embrittlement zone cannot occur during other heat treatments previously carried out in the piezoelectric thin-film transfer method.

According to one embodiment, step a) of providing a bulk handling substrate of the method for manufacturing a donor substrate according to the disclosure may comprise using the bulk handling substrate remnant obtained after step f) of the transfer method described above.

In this way, part of the bulk handling substrate can be recycled and reused after having already been used in a transfer method. This reduces the costs associated with the production of bulk handling substrates for the manufacture of donor substrates for piezoelectric thin-film transfer, and thus the costs associated with the production of POI substrates.

In one embodiment, a step g) for treating the free surface of the bulk handling substrate remnant can be carried out after step f) of the transfer method described above.

In this way, the free surface of the remaining bulk handling substrate is free of particles, and the bulk handling substrate remnant can be reused as a bulk handling substrate to manufacture a donor substrate. For example, the treatment step g) is a CMP-type cleaning step or a cleaning step using a cleaning spray.

### BRIEF DESCRIPTION OF THE DRAWINGS

The present disclosure and its advantages will be explained in greater detail below by way of preferred embodiments and with particular reference to the following accompanying figures, wherein the reference numbers identify features of the present disclosure.

FIG. 1A schematically shows a method for manufacturing a donor substrate according to a first embodiment of the present disclosure.

FIG. 1B schematically shows a method for manufacturing a donor substrate according to a variant of the first embodiment of the disclosure.

FIG. 2 schematically shows a method for manufacturing a donor substrate according to a second embodiment of the disclosure.

FIG. 3A schematically shows steps a) to d) of a method for transferring a piezoelectric thin film according to a third embodiment of the disclosure.

FIG. 3B schematically shows steps e) and f) of the method for transferring a piezoelectric thin film according to the third embodiment of the disclosure shown in FIG. 3A.

FIG. 3C shows a diagram of the method for transferring a piezoelectric thin film according to the third embodiment of the disclosure.

FIG. 3D schematically shows a method for transferring a piezoelectric thin film according to a variant of the third embodiment of the disclosure.

FIG. 4A schematically shows a method for transferring a piezoelectric thin film according to a fourth embodiment of the disclosure.

FIG. 4B schematically shows a method for manufacturing a donor substrate according to a fifth embodiment of the disclosure.

### DETAILED DESCRIPTION

The disclosure will be described in more detail using advantageous embodiments in an exemplary manner and with reference to the drawings. The embodiments described are merely possible configurations and it should be borne in mind that individual features as described above may be provided independently of each other or may be omitted altogether when implementing the present disclosure.

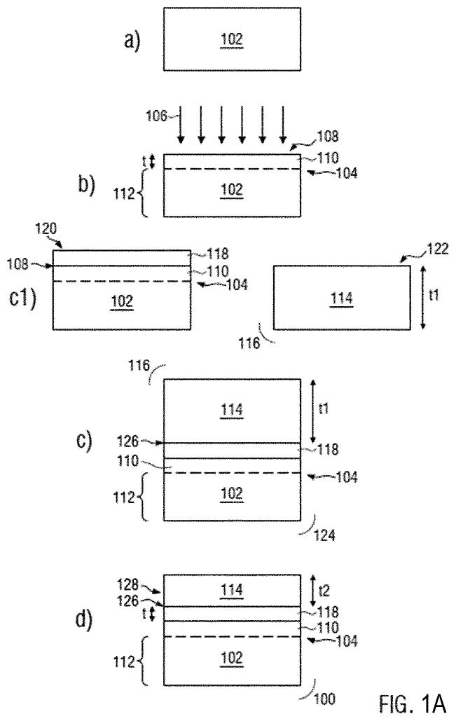

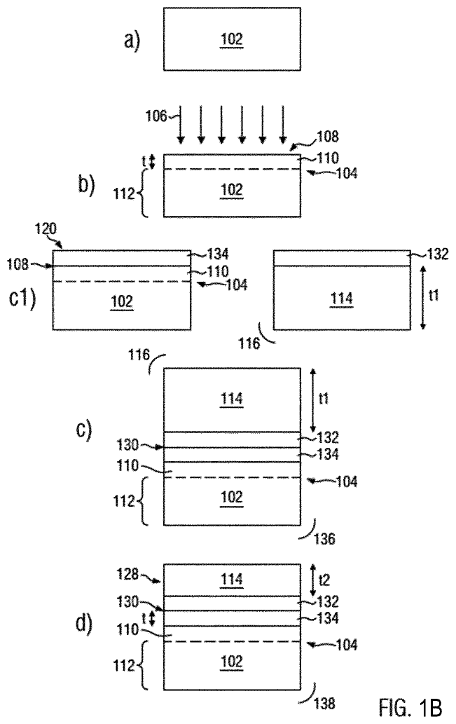

FIG. 1A depicts a method for manufacturing a donor substrate according to a first embodiment of the disclosure.

The method for manufacturing a donor substrate 100 begins with step a) of providing a bulk handling substrate 102. A bulk substrate is a substrate based on a single material, typically between 300 μm and 800 μm thick.

The bulk handling substrate 102 is advantageously made of a material whose coefficient of thermal expansion is close to that of the material of the final support substrate onto which the piezoelectric thin film is to be transferred. “Close to” means that the difference in the coefficient of thermal expansion between the material of the bulk handling substrate 102 and the material of the final support substrate is less than or equal to 5%, and preferably equal to or close to 0%.

The bulk handling substrate 102 can be a Silicon-based substrate. In one embodiment, the bulk handling substrate 102 can also be based on Sapphire (AI₂O₃), Aluminum Nitride (AIN), Silicon Carbide (SiC) or Gallium Arsenide (GaAs). The bulk handling substrate 102 can be a crystalline or polycrystalline substrate.

According to the disclosure, step b) involves forming an embrittlement zone 104 in the bulk handling substrate 102. The formation of the embrittlement zone 104 is achieved by a step b) of implanting 106 atomic or ionic species into the bulk handling substrate 102. The atomic or ionic implantation 106 is performed on the free surface 108 of the bulk handling substrate 102. The atomic or ionic implantation 106 can be performed in such a way that the embrittlement zone 104 is located inside the bulk handling substrate 102 at a depth t from the free surface 108 and separates a film 110 from the remnant substrate 112 of the bulk handling substrate 102. The atomic or ionic species are implanted at a given depth t of the bulk handling substrate 102, which determines the thickness t of the film 110. The thickness t is on the order of 300 nm, in particular, less than 300 nm.

The ionic implantation 106 can be a hydrogen H+ ion or a helium He2+ ion implantation, or a hydrogen H and helium He ion co-implantation. The implantation dose of ionic species is less than 6×10¹⁶ cm⁻², in particular, the implantation dose is between 4×10¹⁶ cm⁻2 and 6×10¹⁶ cm⁻² for a Silicon handling substrate.

In one embodiment, surface treatment steps on the free surface 108 of the bulk handling substrate 102 can be performed prior to the implanting 106 of the bulk handling substrate 102. For example, an RCA-type cleaning treatment.

In step c), a piezoelectric material 114 is provided above the bulk handling substrate 102.

This is preferably a bulk substrate 116 formed from a single piezoelectric material 114 whose thickness t1 is typically on the order of at least 300 μm, preferably between 300 μm and 800 μm.

The piezoelectric material 114 can be, for example, Lithium Tantalate (LTO), Lithium Niobate (LNO), Aluminum Nitride (AIN), Lead Zirconate Titanate (PZT), Langasite (LGS) or Langatate (LGT).

According to the present disclosure, a step cl) of providing at least one intermediate film 118 between the bulk handling substrate 102 and the piezoelectric material 114 is performed before step c), such that the intermediate film 118 is sandwiched between the bulk handling substrate 102 and the piezoelectric material 114.

The intermediate film 118 can be provided on the bulk handling substrate 102, in particular, on the free surface 108 of the bulk handling substrate 102. The intermediate film 118 can be deposited directly on the free surface 108 of the bulk handling substrate 102. The intermediate film 118 can be formed on the free surface 108 of the bulk handling substrate 102 by spin coating or by a thermal or plasma-assisted growth technique such as plasma enhanced chemical vapor deposition (PECVD) or physical vapor deposition (PVD).

Before the intermediate film 118 is formed, one or more steps of cleaning, brushing or polishing the free surface 108 of the bulk handling substrate 102 can be carried out to remove the presence of particles and dust, thus obtaining a cleaner free surface 108 and a better-quality intermediate film 118.

The intermediate film 118 formed on the bulk handling substrate 102 can be a dielectric film, for example a film based on Silicon Oxide SiOx, or based on Silicon Nitride Si₃N₄ or a film comprising a combination of Nitride and Silicon Oxide SiOxNy, or based on Tantalum Oxide Ta₂O₅, based on Aluminum Oxide AI₂O₃, Hafnium Oxide HfO₂, and Zirconium Oxide ZrO₂. Depending on the bonding technology used, the intermediate film 118 formed on the bulk handling substrate 102 can also be a film of amorphous Silicon or Carbon or metal.

The intermediate film 118 has a thickness of between 2 nm and 1000 nm.

In one variant, the intermediate film 118 formed on the bulk handling substrate 102 can be a photopolymerizable polymer film, in particular, based on thiolene resin. The polymer film 118 used in the present disclosure can be, for example, a film marketed under the reference “NOA 61” by NORLAND PRODUCTS. In this case, the thickness of the polymer film 118 is preferably between 1 and 10 μm.

The polymer film 118 alone enables good adhesion to another film or substrate. Indeed, after the assembly step of the donor substrate manufacturing method, a step of treating the polymer film 118 to obtain a cross-linked polymer film for bonding the handling substrate 102 to the piezoelectric material 114 can be performed. A cross-linking treatment can be carried out on the polymer film 118 using heat, pressure, a change in pH or irradiation by a luminous flux, preferably a laser. The light radiation, or luminous flux, is preferably ultraviolet (UV) radiation, preferably with a wavelength between 320 nm and 365 nm.

Thus, during the assembly step included in step c), the piezoelectric material 114 is assembled with the bulk handling substrate 102 to form a heterostructure 124, by contacting the intermediate film 118 with the piezoelectric material 114. Thus, the assembly interface 126 is located between the piezoelectric material 114 and the intermediate film 118 of the bulk handling substrate 102.

According to the disclosure, a step d) of thinning the piezoelectric material 114 is carried out after the assembly step of step c). The thinning is carried out by grinding or by a chemical etching method of the piezoelectric material 114 to reduce the thickness t₁ of the piezoelectric material 114 to obtain a piezoelectric film 128 with a thickness t₂ on the order of 20 μm, or even between 5 μm and 20 μm.

Thus, the bulk handling substrate/piezoelectric material assembly 102, also known as the donor substrate 100, is achieved at the end of step d) of the method comprising a piezoelectric film 128 20 μm or between 5 μm and 20 μm thick on a bulk handling substrate 102 comprising an embrittlement zone 104, with an assembly interface 126 achieved by an intermediate film 118 sandwiched between the bulk handling substrate 102 and the film 128 of piezoelectric material 114.

In one variant, the intermediate film 118 can be provided on the piezoelectric material 114 instead of on the bulk handling substrate 102, in particular, on the free surface of the piezoelectric material 114.

In another embodiment, the piezoelectric material 114 can be supplied directly on the bulk handling substrate 102, without the presence of an intermediate film 118 between the two.

FIG. 1B shows a variant of the first embodiment of the disclosure wherein step c1) of providing an intermediate film 118 is different from the first embodiment. The intermediate film 118 is deposited on the bulk handling substrate 102 and on the piezoelectric material 114. All other steps a), b), c) and d) are the same as in the first embodiment. All features in common with the first embodiment and using the same reference number as above will not be described again, but reference is made to their detailed description above.

In step c1), an intermediate film 132 is provided on the piezoelectric material 114 and an intermediate film 134 is provided on the bulk handling substrate 102. The assembly 136 of the bulk handling substrate 102 with the piezoelectric material 114 is then carried out at the interface between the two intermediate films 132, 134. In particular, the intermediate films 132, 134 are based on dielectric material, and the interface 130 is made with oxide-oxide bonds, in particular, a Si—O—Si bond, which enables stable molecular force bonding.

In another embodiment, the intermediate films 132, 134 provided on the piezoelectric material 114 and on the bulk handling substrate 102 are composed of different dielectric materials. For example, the intermediate film 132 provided on the bulk handling substrate 102 is a film of Silicon Nitride Si₃N₄, while the intermediate film 134 provided on the piezoelectric material 114 is a film of Silicon Oxynitride SiON. The bulk handling substrate 102 is then joined to the piezoelectric material 114 at the interface 130 between two Si₃N₄-SiON dielectric films, which also provides a stable bond.

A donor substrate 138 is thus obtained after step d) of the method, comprising a piezoelectric film 128 with a thickness t₂ of 20 μm or between 5 μm and 20 μm on a bulk handling substrate 102 comprising an embrittlement zone 104, with an assembly interface 130 made by two intermediate films 132, 134 based on different materials.

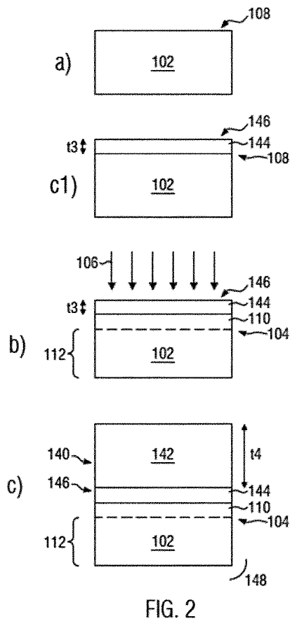

FIG. 2 shows a second embodiment of the disclosure of the donor substrate manufacturing method. In this second embodiment, step c1) of providing an intermediate film and step c) of providing the piezoelectric material are different from those described in the first embodiment of the manufacturing method. Steps a) and b) are the same as those described in the first embodiment of the manufacturing method. All features in common with the first embodiment and using the same reference number as above will not be described again, but reference is made to their detailed description above.

According to the second embodiment of the disclosure, step c) of providing a piezoelectric material 142 over the bulk handling substrate 102 is performed by epitaxial deposition of a film 140 based on piezoelectric material 142.

To be able to provide a film 140 based on piezoelectric material 142 by epitaxial deposition, a step c1) is necessary to provide a seed film 144 for successive epitaxial growth of a film. This step c1) of providing a seed film 144 is also carried out by epitaxial deposition of a film based on piezoelectric material 142 at temperatures between 970 °C and 1050 °C. For example, the piezoelectric material 142 deposited is based on Gallium Nitride GaN, but it can also be another type of material, such as Aluminum Nitride AIN. The seed film 144 has a thickness 6 of 50 nm to 500 nm.

According to the method of the second embodiment, when step cl) is completed and the seed film 144 is deposited on the free surface 108 of the bulk handling substrate 102, step b) of implanting 106 of the bulk handling substrate 102 is performed to create the embrittlement zone 104 of the bulk handling substrate 102. The implanting 106 of atomic or ionic species is carried out through seed film 144 into the interior of bulk handling substrate 102, incident on the top surface 146 of the seed film 144.

In this embodiment, the implantation dose is less than 6×10¹⁶ cm⁻², in particular, less than 5×10¹⁶ cm⁻². Such a dose of implantation in the bulk handling substrate 102 increases the temperature at which fracture of the bulk handling substrate 102 along an embrittlement zone 104 in the bulk handling substrate 102 can be achieved. For example, for a bulk handling substrate 102 based on Silicon Carbide SiC, fracture of the bulk handling substrate 102 can be achieved as early as 850 °C, but using an implant dose of 4×10¹⁶ cm⁻² results in fracture of the bulk handling substrate 102 at a temperature of 950 °C

Once step b) 106 has been implanted on the bulk handling substrate 102, step c) the film 140 of 142 piezoelectric material is epitaxially deposited. This epitaxial deposition is carried out directly on the seed film 144, enabling a good-quality film 140 of piezoelectric material 142 to be deposited epitaxially.

Step c) of epitaxial deposition of piezoelectric material 142 is carried out at a temperature below 950 °C, in particular, 900 °C. The thickness of the film 140 of piezoelectric material 142 formed is 20 μm, in particular, less than 100 μm.

After step c) of the method, a donor substrate 148 is obtained comprising a film 140 of piezoelectric material 142 with a thickness of 20 μm or less than 20 μm on a bulk handling substrate 102 comprising an embrittlement zone 104, with a seed film 144 sandwiched between the film 140 of piezoelectric material 142 and the bulk handling substrate 102.

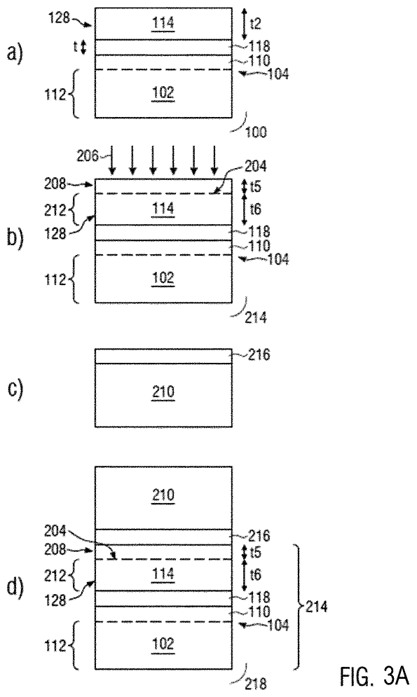

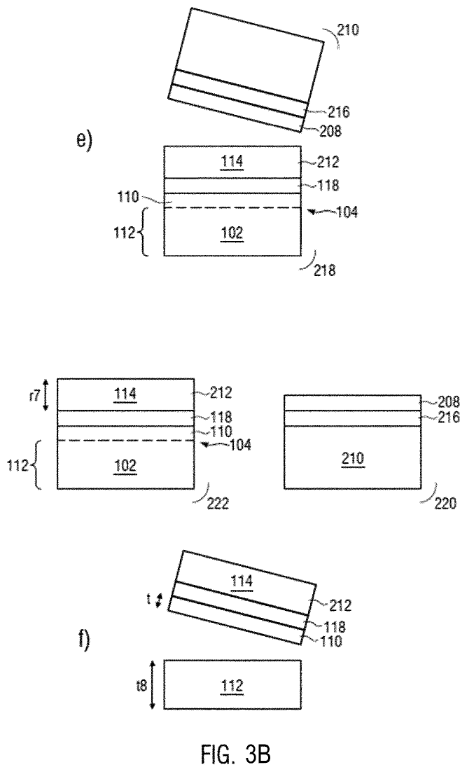

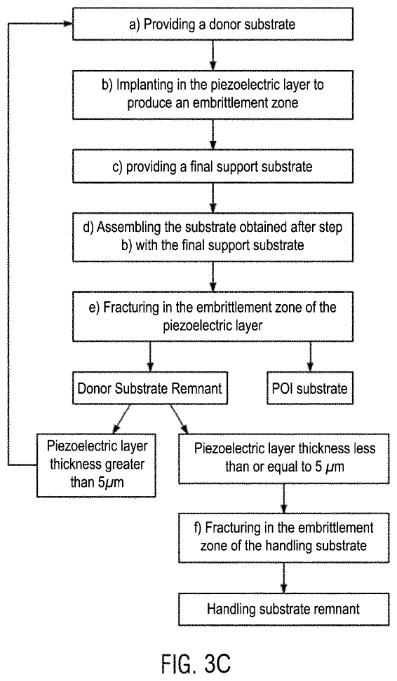

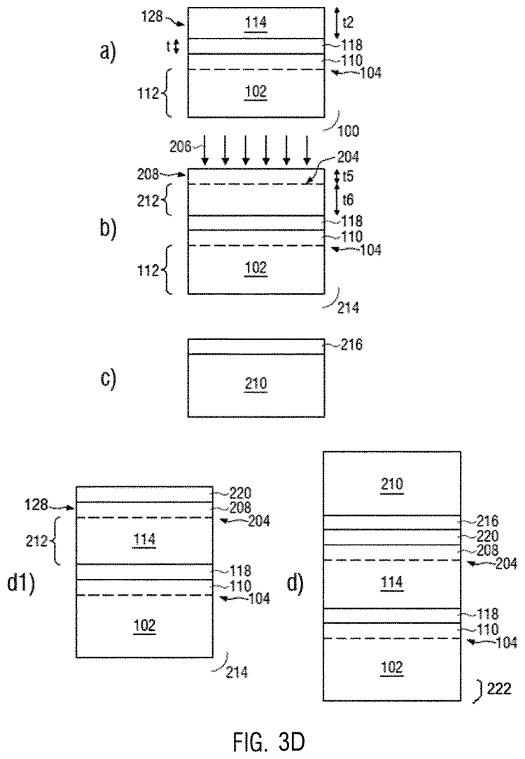

The method for transferring a piezoelectric thin film according to a third embodiment of the disclosure is shown schematically for clarity in two figures, FIGS. 3A and 3B. However, the transfer method according to the disclosure comprises all the steps a) to f) illustrated in FIGS. 3A and 3B.

The method of transferring a piezoelectric film onto a final support substrate according to the disclosure comprises the step of providing a donor substrate obtained by implementing the method of manufacturing a donor substrate described in relation to FIGS. 1A, 1B and 2 according to the first embodiment of the disclosure and its variants and according to the second embodiment of the disclosure and its variants.

The method for transferring a piezoelectric thin film begins with step a) of providing a substrate 200. The substrate 200 corresponds to a donor substrate as described above and according to the disclosure. That is, the substrate 200 may be the donor substrate 100 obtained in step d) of FIG. 1A, or the donor substrate 138 obtained in step d) of FIG. 1B, or the donor substrate 148 obtained in step c) of FIG. 2.

In all these cases, the donor substrate provided in step a) of the transfer method comprises a film 128, 140 of piezoelectric material 114, 122 with a thickness of 20 μm or less than 20 μm, on a bulk handling substrate 102 comprising an embrittlement zone 104, with at least one intermediate film 118, 132, 134, 144 sandwiched between the bulk handling substrate 102 and the film 128, 140 of piezoelectric material 114, 122.

The at least one intermediate film 118, 132, 134, 144 may be a dielectric film 118, 132, 134, a polymer film 118, whether cross-linked or not, or a seed film 144 epitaxially deposited on the bulk handling substrate 102.

FIGS. 3A and 3B illustrate the transfer method using the donor substrate 100 obtained in FIG. 1A, but as indicated above, donor substrates 138 and 148 can also be used. FIG. 3A illustrates steps a) to d) and FIG. 3B illustrates steps e) and f) of the transfer method.

The method then comprises a step b) of forming an embrittlement zone 204 within the film 128 of piezoelectric material 114 of the donor substrate 100, so as to delimit a piezoelectric film 208 to be transferred onto a final support substrate 210.

This step of forming an embrittlement zone 204 is carried out by implanting atomic or ionic species 206 into the film 128 of piezoelectric material 114 of the donor substrate 100. The atomic or ionic species implantation 206 is carried out in such a way that the embrittlement zone 204 is located inside the film 128 of piezoelectric material 114 and separates a piezoelectric film 208 from the rest 212 of the film 128 of piezoelectric material 114. The atomic or ionic species are implanted at a given depth of the piezoelectric film 124, which determines the thickness t₅ of the piezoelectric film 208 to be transferred and the thickness to of the rest 212 of the film 128 of piezoelectric material 114. The thickness t₅ is typically between 50 nm and 1 μm, in particular, on the order of 600 nm.

The resulting donor substrate 214 comprises an embrittlement zone 204 separating the piezoelectric film 208 to be transferred from the rest 212 of the film 128 of piezoelectric material 114.

Step c) of the transfer method according to the disclosure comprises providing a final support substrate 210. The final substrate is a bulk silicon-based substrate. The final support substrate 210 can also be a bulk substrate based on Silicon Carbide SIC, polySiC, polyAIN or a sintered ceramic material.

According to the disclosure, the final support substrate may comprise a film 216. The film 216 can be a dielectric film, for example a Silicon Oxide-based film, or a Silicon Nitride Si₃N₄ film, or a film comprising a combination of Nitride and Silicon Oxide (Silicon Oxynitride) SiOxNy. The film 216 can also be formed by Aluminum Oxide AI₂O₃, Hafnium Oxide HfO₂ or Tantalum Oxide TazOs or other materials with specific functional properties, for example as a diffusion barrier, an acoustic impedance value, or the trapping of contaminating species. The thickness of the film 216 is between 2 nm and 1000 nm. Depending on the bonding technology used, the film 216 can also be a silicon or amorphous carbon or metal film.

Step d) of the transfer method according to the disclosure comprises assembling the donor substrate 214 obtained in step b) of the method with the final support substrate 210 to obtain a final support substrate/donor substrate assembly that forms the heterostructure 218. The donor substrate 214 is assembled onto the final support substrate 210 at the film 216, so that the film 128 of piezoelectric material 114 of the donor substrate 214 is in contact with the film 216 of the support substrate 210.

Next, a step e) of making a fracture along the embrittlement zone 204 of the film 128 of piezoelectric material 114 to separate the piezoelectric film 208 from the remnant 212 of the film 128 of piezoelectric material 114 of the donor substrate is performed. This fracturing step can be performed thermally or mechanically. During thermal separation, the temperature used is below 600 °C, in particular, below 300 °C. For example, a heat treatment of 5 hours at 200 °C can be used to make the fracture. The heat treatment performed makes it possible to fracture only the embrittlement zone 204 of the film 128 of piezoelectric material 114. Indeed, the embrittlement zone 104 present in the bulk handling substrate 102 is not fractured during this heat treatment, as the heat input is not high enough for this. The temperature used is too low to fracture the embrittlement zone 104 in the bulk handling substrate 102.

A piezoelectric on insulator (POI) substrate 220 illustrated in step e) of FIG. 3B is produced by the piezoelectric film transfer method according to the disclosure and comprises a final support substrate 210, a film 216 and a piezoelectric film 208 with a thickness of between 50 nm and 1 um, in particular, on the order of 600 nm.

At the end of step e) of the transfer method, there also remains a donor substrate 222 comprising the bulk handling substrate 102 with its embrittlement zone 104, the intermediate film 118 and the remnant 212 of the film 128 of piezoelectric material 114. The piezoelectric film remnant 212 has a thickness t₆ less than the thickness t₂ of the film 128. Thus, the donor substrate remnant 222 can be reused in a transfer method according to steps a) and e) described above as long as the thickness to of the piezoelectric film 212 of the donor substrate remnant 222 obtained in step e) is greater than 5 μm.

Thus, according to the disclosure, steps a) to e) of the transfer method are repeated at least once. The repetition of steps a) to e) of the transfer method is illustrated with a diagram in FIG. 3C.

From the second iteration onwards, step a) of the method of providing a substrate is carried out with the substrate 222 corresponding to the remnant of the donor substrate 100 obtained at the end of step e) of the previous iteration, i.e., the donor substrate remnant 222.

In the second iteration of the method, an implantation step b) 206 is performed in the piezoelectric film 212 of the donor substrate remnant 222 to produce an embrittlement zone in the piezoelectric film 212, being the piezoelectric film remaining on the donor substrate remnant 222 after the transfer of a thin piezoelectric film 208 onto the final support substrate 210 in the first iteration of the transfer method.

Steps b), c), d) and e) are repeated to again obtain a POI substrate 230 (not shown) according to step e) of the first iteration. The steps are the same as those described above for the transfer method.

Similarly, after the second iteration of step e) of the method, a donor substrate remnant 222, called donor substrate 232 (not shown), is obtained with a piezoelectric film 242 being thinner than the piezoelectric film 212, as a piezoelectric thin film has been transferred from the piezoelectric film 212 to the final support substrate to form the POI substrate 230.

At the end of step e) of the second iteration, if the thickness of the piezoelectric film remnant 242 in the donor substrate 232 is greater than 5 μm, a further iteration of steps a) to e) is performed to obtain another POI substrate, and so on until the thickness of the remaining piezoelectric film 242 of the donor substrate remnant 222 is equal to or less than 5 μm.

When the thickness of the remaining piezoelectric film 242 in the donor substrate remnant 232 is equal to or less than 5 μm, a step f) is then performed. The transfer method according to steps a) to e) is not repeated.

Step f) is a fracturing step along the embrittlement zone 104 of the bulk handling substrate 102 of the remnant of the substrate 232. In this way, the film 110 of the bulk handling substrate 102 bounded by the embrittlement zone 104 is separated from the remnant 112 of the bulk handling substrate 102. Similarly, the intermediate film 118 and the piezoelectric film remnant 212 positioned on film 110 are also separated from the remnant 112 of the bulk handling substrate 102.

Thus, after step f) of fracturing the bulk handling substrate 102 along the embrittlement zone 104, a remnant 112 of the bulk handling substrate 102 having a thickness t8 is obtained. The thickness to of the remnant 112 of the bulk handling substrate 102 is less than the thickness t′ typical of a bulk handling substrate 102. Indeed, the thickness t₈ of the remnant 112 of the bulk handling substrate 102 corresponds to the thickness t′ of the initial bulk handling substrate 102 in the donor substrate manufacturing method minus the thickness t of the film 110 of the bulk handling substrate 102 removed during the fracturing of the bulk handling substrate 102.

This fracturing step is carried out by heat treatment.

When the support substrate supplied in step a) corresponds to the donor substrate 100 or 138 of FIG. 1A or 1B and has been manufactured using the method for manufacturing the first embodiment and its variants, the temperature required for the fracture heat treatment along the embrittlement zone of the bulk handling substrate is between 500 °C and 600 °C

When the support pseudo-substrate supplied in step a) corresponds to the donor substrate 148 of FIG. 2 and has been manufactured using the method for manufacturing the second embodiment and its variants, the temperature required for the fracture heat treatment along the embrittlement zone 104 of the bulk handling substrate 102 is greater than 950 °C, in particular, 1000 °C.

This difference in fracture treatment temperature is due to the manufacturing technique used for the piezoelectric material of the donor substrate. Indeed, it is necessary for the fracture of the embrittlement zone of the bulk handling substrate to take place at different, and above all higher, temperatures than those used for the fracture of the embrittlement zone of the piezoelectric material of the fabricated donor substrate. Fracturing of the embrittlement zone of the piezoelectric material must be carried out before the fracturing of the embrittlement zone of the bulk handling substrate, i.e., at lower temperatures.

Thus, the method for transferring a piezoelectric thin film according to the disclosure comprises two different fractures at two different locations on the donor substrate, a first fracture along the embrittlement zone in the piezoelectric film and a second fracture along the embrittlement zone in the bulk handling substrate. The two fractures are produced by different heat inputs, so that the two fractures cannot be produced at the same time in the method. Both fractures can also be treated mechanically. Thus, the piezoelectric thin-film transfer method according to the third embodiment of the disclosure makes it possible to obtain several piezoelectric-on-insulator (POI) substrates from a single fabricated donor substrate, and also makes it possible to obtain a bulk handling substrate remnant, which can be used again in other manufacturing methods.

FIG. 3D shows a variant of the third embodiment of the disclosure wherein step d) of attaching the donor substrate to the final support substrate to obtain a donor substrate/final support substrate assembly is different from the third embodiment. All other steps a), b), c), e) and f) are the same as in the third embodiment. All features in common with the third embodiment and using the same reference number as above will not be described again, but reference is made to their detailed description above.

In this variant, before step d) of assembling the donor substrate 214 obtained in step b) of the method to the final support substrate 210, a step of depositing an additional film 220 can be performed on the donor substrate 214. The additional film 220 can be formed on the film 128 of piezoelectric material 114 by spin coating or by a thermal or plasma-assisted growth technique such as plasma enhanced chemical vapor deposition (PECVD) or physical vapor deposition (PVD).

The film 220 can be a dielectric film, for example a silicon oxide-based film, or a silicon nitride Si₃N₄ film, or a film comprising a combination of nitride and silicon oxide SiOxNy. The film 220 can also be formed by Aluminum Oxide AI₂O₃, Hafnium Oxide HfO₂, or Tantalum Oxide Ta₂O₅ or other materials with specific functional properties, for example as a diffusion barrier, an acoustic impedance value, or the trapping of contaminating species. The thickness of the film 220 is between 2 nm and 1000 nm.

Thus, during step d) of assembly, the assembly interface takes place between the additional film 220 of the donor substrate 214 and the film 216 of the final support substrate 210. This interface provides a stable bond between the donor substrate 214 and the final support substrate 210.

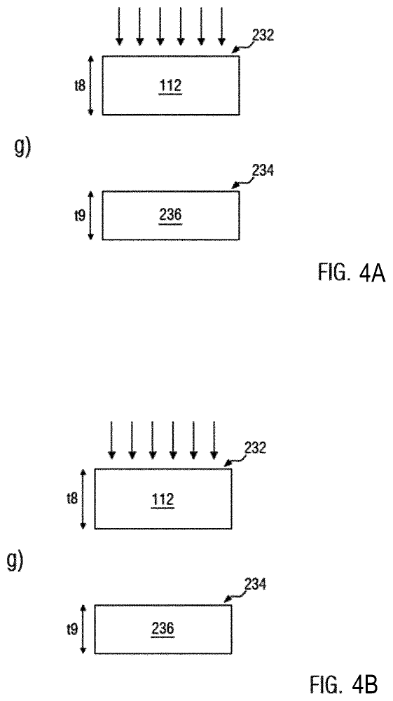

FIG. 4A schematically shows a method for manufacturing a donor substrate according to a fourth embodiment of the disclosure. In the fourth embodiment, step a) of providing a bulk handling substrate is different from the first embodiment. All other steps b), c), and d) are the same as in the first embodiment. All features in common with the first embodiment and using the same reference number as above will not be described again, but reference is made to their detailed description above.

According to the fourth embodiment of the disclosure, step a) of providing a bulk handling substrate comprises using the remnant of the bulk handling substrate obtained after step f) of the transfer method according to the third embodiment of the disclosure and its variants.

At the end of fracturing step f) of the transfer method of the third embodiment, as illustrated in FIG. 3A, a remnant substrate 112 of the bulk handling substrate 102 of thickness t₈ is obtained. The thickness to of the remnant 112 of the bulk handling substrate is less than the thickness t′ typical of a bulk handling substrate used for step a) of the donor substrate manufacturing method, as described in FIG. 1A.

After step f) of the transfer method, a step g) of cleaning the surface 232 of the remaining 112 of the 102 handling substrate is carried out. This cleaning step may comprise several different treatments, such as a DSS spray clean treatment followed by a CMP (chemical mechanical planarization) cleaning step. CMP cleaning makes it possible to remove a 550 nm-thick surface from the remnant 112 of the 102 handling substrate. Thus, a handling substrate 236 with a final thickness to is obtained at the end of step g) having a clean free surface 234. Thickness to is less than to, the thickness of the remnant substrate 112 after the fracture step f).

These cleaning treatments are necessary to render the surface 234 of the handling substrate 236 free of detritus and give it a roughness that allows the handling substrate 236 to be used again in a manufacturing method according to the first embodiment and its variants.

Once step g) has been carried out, the following steps a) to d) of the manufacturing method according to the first embodiment and its variants can be carried out to obtain a donor substrate for use in a piezoelectric thin-film transfer method.

Thus, the manufacturing method according to the disclosure makes it possible to reuse a bulk handling substrate that has already been used in a piezoelectric thin-film transfer method instead of having to provide a new bulk handling substrate, which increases the cost of the method for manufacturing a POI substrate.

Recycling a part of the bulk handling substrate according to the disclosure, therefore, makes it possible to reduce the cost of the method for manufacturing a POI substrate.

FIG. 4B schematically shows a method for manufacturing a donor substrate according to a fifth embodiment of the disclosure. In the fifth embodiment, step a) of providing a bulk handling substrate is different from the second embodiment. All other steps b), c), and d) are the same as in the second embodiment. All features in common with the second embodiment and using the same reference number as above will not be described again, but reference is made to their detailed description above.

According to the fifth embodiment of the disclosure, step a) of providing a bulk handling substrate comprises using the remnant of the substrate obtained after step f) of the transfer method according to the third embodiment of the disclosure or its variants.

At the end of fracturing step f) of the transfer method of the third embodiment, as illustrated in FIG. 3A, a remnant substrate 112 of the bulk handling substrate 102 of thickness to is obtained. The thickness to of the remnant 112 of the bulk handling substrate is less than the thickness t′ typical of a bulk handling substrate used for step a) of the donor substrate manufacturing method, as described in FIG. 4A.

After step f) of the transfer method, a step g) of cleaning the surface 232 of the remnant substrate 112 of the bulk handling substrate 102 is carried out. This treatment step comprises one or more heat treatments, at temperatures above 950 °C, in particular, at temperatures of 1000 °C.

This heat treatment renders the surface 234 of the remnant 112 of the handling substrate 236 free of detritus so that it can be used again in a manufacturing method according to the second embodiment and its variants.

Once step g) has been carried out, the following steps a) to d) of the manufacturing method according to the second embodiment and its variants can be carried out to obtain a donor substrate for use in a piezoelectric thin-film transfer method.

Thus, the manufacturing method according to the disclosure makes it possible to reuse a bulk handling substrate that has already been used in a piezoelectric thin-film transfer method instead of having to provide a new bulk handling substrate, which increases the cost of the method for manufacturing a POI substrate.

Recycling a part of the bulk handling substrate according to the disclosure, therefore, makes it possible to reduce the cost of the method for manufacturing a POI substrate.

The embodiments described are merely possible configurations, and it should be borne in mind that the individual features of the different embodiments can be combined with each other or provided independently of each other.

1. A method for transferring a piezoelectric thin film, comprising:
a) providing a donor substrate comprising:
a bulk handling substrate with an embrittlement zone; and
a piezoelectric material,
the piezoelectric material, being above the bulk handling substrate;
b) forming an embrittlement zone inside the piezoelectric material, of the donor substrate;
c) providing a final support substrate;
d) attaching the donor substrate to the final support substrate to obtain a donor substrate/final support substrate assembly; and
e) fracturing the piezoelectric material along the embrittlement zone of the piezoelectric material to separate a piezoelectric film from a remnant of the donor substrate.

2. The method of claim 1, wherein the fracturing of the piezoelectric material along the embrittlement zone of the piezoelectric material is performed at a temperature lower than a temperature used to perform fracturing at the embrittlement zone of the bulk handling substrate of the donor substrate.

3. The method of claim 1, wherein steps a) to e) are repeated at least once and, starting with the second iteration, step a) is carried out with the remnant of the donor substrate obtained at the end of step e) of the previous iteration.

4. The method of claim 3, wherein steps a) to e) are repeated as long as the thickness of the piezoelectric film of the remnant of the donor substrate obtained in step e) is greater than 5 μm.

5. The method of claim 1, wherein a step f) of fracturing the remnant of the donor substrate at the embrittlement zone of the bulk handling substrate is carried out after step e).

6. The method of claim 5, wherein the step f) is carried out when the thickness of the piezoelectric film of the remnant of the donor substrate obtained in step e) is equal to or less than 5 μm, to obtain a remnant of bulk handling substrate

7. The method of claim 5, wherein the step f) of fracturing the remnant of the donor substrate along the embrittlement zone of the bulk handling substrate is carried out by heat treatment.

8. The method of claim 1, wherein the donor substrate provided in step a) is obtained by implementing a method of manufacturing a donor substrate for transferring a piezoelectric film onto a final support substrate, the method for manufacturing a donor substrate for transferring a piezoelectric film onto a final support substrate comprising the steps of:
a) providing a bulk handling substrate
c) providing a piezoelectric material above the bulk handling substrate and further comprising a step b) of implanting the bulk handling substrate to provide an embrittlement zone in the bulk handling substrate prior to the step c) of supplying-providing the piezoelectric material.

9. The method of claim 8, wherein the step a) of providing a bulk handling substrate comprises using the remnant of the bulk handling substrate obtained after a step f) of fracturing the remnant of the donor substrate at the embrittlement zone of the bulk handling substrate carried out after the step e).

10. The method of claim 9, wherein a step g) of treating the surface of the remnant of the bulk handling substrate is carried out after the step f).

11. The method claim 8, wherein the step b) of implanting the bulk handling substrate is carried out with an implantation dose of less than 6×10¹⁶ cm⁻².

12. The method of claim 8, wherein a step cl) of providing an intermediate film between the bulk handling substrate and the piezoelectric material is performed prior to the step c) of providing a piezoelectric material above the bulk handling substrate.

13. The method of claim 8, wherein the step c) of providing a piezoelectric material above the bulk handling substrate comprises providing a bulk substrate based on piezoelectric material.

14. The method of claim 13, wherein the step c) of providing a piezoelectric material above the bulk handling substrate further comprises a step of assembling the bulk handling substrate with the bulk substrate based on piezoelectric material.

15. The method of claim 8, wherein a step d) of thinning the piezoelectric material is carried out.

16. The method of claim 15, wherein the step d) of thinning the piezoelectric material is performed to obtain a film of the piezoelectric material with a thickness of 30 μm or less.

17. The method of claim 8, wherein the step c) of providing a piezoelectric material above the bulk handling substrate is performed by epitaxial deposition of a film based on the piezoelectric material on the bulk handling substrate.

18. The method of claim 17, wherein the epitaxial deposition step is carried out at a temperature below 950 °C.

19. The method of claim 1, wherein the donor substrate provided in step a) of said the transfer method is characterized in that the embrittlement zone is positioned at a depth t in the bulk handling substrate of 500 nm or less.

20. The method of claim 1, wherein the donor substrate provided in step a) of the transfer method is characterized in that the bulk handling substrate is a Silicon Carbide SiC substrate and the piezoelectric material is Gallium Nitride GaN.
